(19) United States
(12) Patent Application Publication
(10) Pub. No.: US 2025/0371243 A1
(43) Pub. Date: Dec. 4, 2025

(54) IC CELL LAYOUT ALTERNATIVE GEOMETRY VERIFICATION

(71) Applicant: Arm Limited, Cambridge (GB)

(72) Inventors: Ala Srinivasa Rao, Bangalore (IN); Sridhara Basa, Bangalore (IN); Karthik Murali, Bangalore (IN); Sambhava Thonse Pai, Bangalore (IN)

(21) Appl. No.: 18/680,859

(22) Filed: May 31, 2024

(51) Int. Cl. G06F 30/398; G06F 30/392

(52) U.S. Cl. CPC G06F 30/398; G06F 30/392

(57) ABSTRACT

Briefly, example apparatuses, articles of manufacture, and/or techniques are disclosed that may be implemented, in whole or in part, to implement, facilitate and/or support integrated circuit design, such as, an IC cell design including alternative position parameters associated with a subset of layer designs of the IC cell design.

### FIELD

The present disclosure relates generally to integrated circuitry, and more particularly, to integrated circuit design.

### BACKGROUND

Standard cells may be used in the IC design process to provide predefined and/or precharacterized building blocks that can be combined to form an chip design. For example, a standard cell library might include cells to implement boolean gates (e.g., AND, OR, NAND, XOR, NOT, etc.), sequential logic components (e.g., flip-flops, latches, etc . . . ), as well as more complex circuit elements (e.g., adders, muxed D-type flip-flops, etc . . . ). A standard cell may have various representations (e.g., “views”), such as a logical view that represents the cell's logical and/or functional operation, a netlist or schematic view that represents the cell's transistor topology (e.g., the cell's transistors as well as their connectivity and ports), and a layout view that represents the physical configuration (e.g., geometries, layers, sizes, etc.) of the cell. To provide different design options, standard cell variants may be included in a design library. For example, variants may be provided with different threshold voltages (Vt) (e.g., low Vt, base Vt, and high Vt), different beta ratios (e.g., ratios between PFET and NFET transistor sizes), drive strengths, transistor fingers, and/or the like.

### BRIEF DESCRIPTION OF THE DRAWINGS

Claimed subject matter is particularly pointed out and distinctly claimed in the concluding portion of the specification. However, both as to organization and/or method of operation, together with objects, features, and/or advantages thereof, it may best be understood by reference to the following detailed description if read with the accompanying drawings in which:

FIG. 1 illustrates an example apparatus including storage circuitry to store an IC cell design, first verification operation parameters, and second operation parameters 113 in accordance with an implementation;

FIG. 2 illustrates another example apparatus in accordance with an implementation;

FIGS. 3A-3D provide examples of a baseline IC layout and layout variants to illustrate various aspects of implementations;

FIGS. 4A-4C illustrate examples of various aspects of an example implementation;

FIG. 5 illustrates an example method of operation in accordance with an implementation;

FIG. 6 illustrates an example system embodiment of an network-connected device providing aspects of an IC design infrastructure in accordance with an implementation.

Reference is made in the following detailed description to accompanying drawings, which form a part hereof, wherein like numerals may designate like parts throughout that are corresponding and/or analogous. It will be appreciated that the figures have not necessarily been drawn to scale, such as for simplicity and/or clarity of illustration. For example, dimensions of some aspects may be exaggerated relative to others, one or more aspects, properties, etc. may be omitted, such as for ease of discussion, or the like. Further, it is to be understood that other embodiments may be utilized. Furthermore, structural and/or other changes may be made without departing from claimed subject matter. References throughout this specification to “claimed subject matter” refer to subject matter intended to be covered by one or more claims, or any portion thereof, and are not necessarily intended to refer to a complete claim set, to a particular combination of claim sets (e.g., method claims, apparatus claims, etc.), or to a particular claim. Therefore, the following detailed description is not to be taken to limit claimed subject matter and/or equivalents.

### DETAILED DESCRIPTION

References throughout this specification to one implementation, an implementation, one embodiment, an embodiment, and/or the like means that a particular feature, structure, characteristic, and/or the like described in relation to a particular example, implementation and/or embodiment is included in at least one example, implementation and/or embodiment of claimed subject matter. Thus, appearances of such phrases, for example, in various places throughout this specification are not necessarily intended to refer to the same implementation and/or embodiment and/or to any one particular implementation and/or embodiment.

Furthermore, it is to be understood that particular features, structures, characteristics, and/or the like described are capable of being combined in various ways in one or more implementations and/or embodiments and, therefore, are within intended claim scope. Unless explicitly indicated to the contrary, reference to “another example” and/or “a further example” does not indicate that the described example is an exclusive alternative to a preceding example. In general, such examples may be alternatives to and/or additions to previous examples.

Placement is a stage of VLSI design where circuit components are placed in a physical layout to implement a logical IC design (e.g., a gate-level netlist). Placement is a complicated constrained optimization problem involving the interplay between many different design constraints. Particularly at advanced process nodes (manufacturing processes and design rules), design constraints may impact the number of locations that a given cell may be located (e.g., “placeability”). Cell variants having equivalent electrical characteristics but alternative physical layouts (“electrically equivalent” (EEQ) or “layout variant” views) may be provided to improve placeability. For example, a standard cell layout view may include designs for different IC layers, such as one or more layers of silicon device geometries (e.g., “front-end-of-the-line” or FEOL layers), device-level interconnects (e.g., “middle-end-of-the-line” or MEOL layer), and intra-cell level interconnects such as metal interconnects and/or vias (e.g., “back-end-of-the-line” or BEOL layers). Layout variant cells may share a portion of their layer designs while differing in other layers. For instance, a layout variant and its archetype/master cell may have the same FEOL and MEOL layers while having different (but electrically equivalent) BEOL layers. Layout variants may be used during placement to avoid various issues and/or meet various design rule constraints, such as, for example, abutment issues that may arise when two cells share a border (e.g., horizontally or vertically neighboring cells), color loop violations, non-alignment of multi-patterning masks at the block level (e.g., multi-patterning power rail masks), unaligned or misaligned pitches, and/or the like.

As indicated above, a given standard cell may have many different functional variants (e.g., with different drive strengths, voltage thresholds, etc . . . ). The standard cell and its functional variants may be accompanied by physical layout variants (“layout variants”) as well, multiplying the total number of variants of a given cell. Additionally, layout variants may be designed towards the end of the design process, after their corresponding standard cell and/or functional variants have been designed. A design rule violation in a layout variant of a particular functional variant may require rework and/or redesign that impacts the cell it was based upon. This may impact the rest of the cell variant designs in a cascading fashion, significantly increasing design time and/or computational resources.

Implementations of the disclosed technology may address these and/or other challenges by providing techniques to improve standard cell design. For example, aspects of the disclosed techniques may enable a standard cell to be designed in view of layout variants that will be developed later. In some implementations, an IC cell design may include a plurality of designs for different cell layers, which comprise position parameters defining the geometries of the corresponding layers. The cell design may further include alternative position parameters for a portion of the cell layers, which may define alternative geometries for potential layout variants. Design verification operations (e.g., design rule checks or “DRCs”) may be performed using the position parameters to verify the cell and design verification operations may be performed using the alternative position parameters to verify a layout variant of the cell. Functional variants of such designs may benefit from the alternative geometry verification, relatively reducing the likelihood of a violation later in the design process. Layout variants based on an IC cell designed as discussed herein may be more likely to pass the verification process, avoiding or reducing rework of the IC cell and/or its functional variants.

At least some examples of the present technique provide an apparatus including storage circuitry to store an integrated circuit (IC) cell design comprising a plurality of IC layer layout designs. In some examples, respective IC layer layout designs may include respective position parameters and the IC cell design may further include respective alternative position parameters associated with a subset of the respective IC layer layout designs. The storage circuitry may further store first verification operation parameters and second verification operation parameters. The first verification operation parameters may be based at least in part on the respective position parameters, and the second verification operation parameters may be based at least in part on the respective alternative position parameters associated with the subset of the respective IC layer layout designs and the respective position parameters of the respective IC layer layout designs corresponding to a complement of the subset.

At least some further examples of the present technique provide a method including storing an integrated circuit (IC) cell design including a plurality of IC layer layout designs. In some implementations, respective IC layer layout designs comprise respective position parameters, and the IC cell design further comprises respective alternative position parameters associated with a subset of the respective IC layer layout designs. In some examples, the method may further include storing first verification operation parameters and storing second verification operation parameters. The first operation parameters may be based at least in part on the respective alternative position parameters associated with the subset of the respective IC layer layout designs and the respective position parameters of the respective IC layer layout designs corresponding to a complement of the subset.

At least some further examples of the present technique provide computer-readable medium storing computer-readable code for implementing an apparatus or performing a method as set out above.

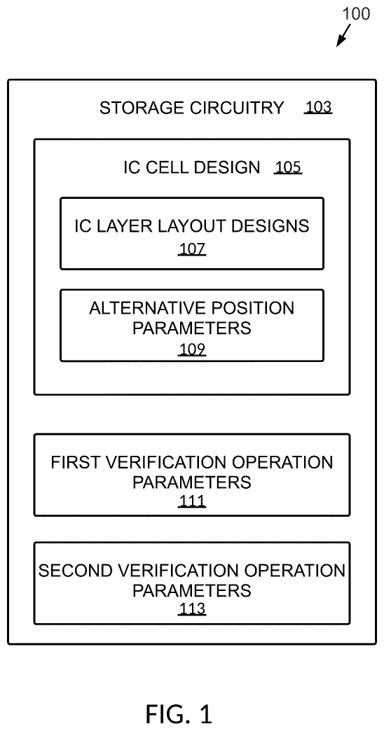

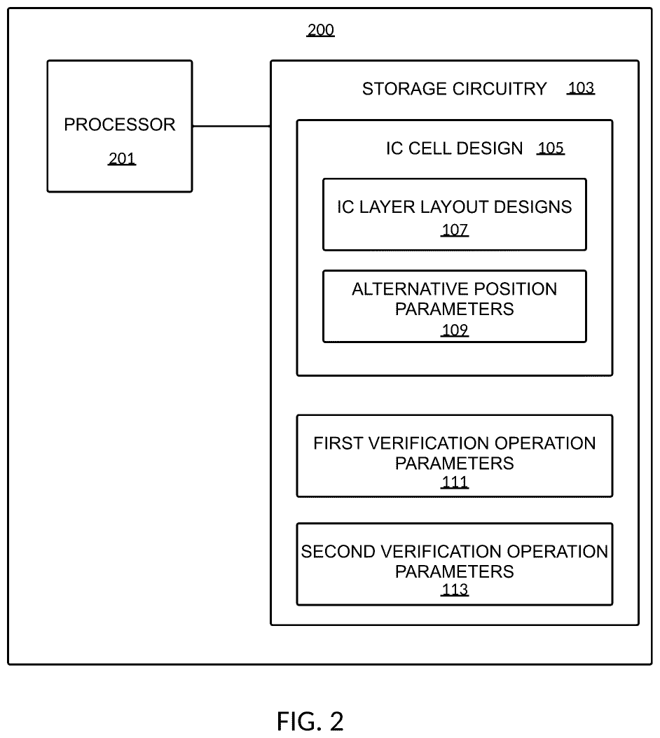

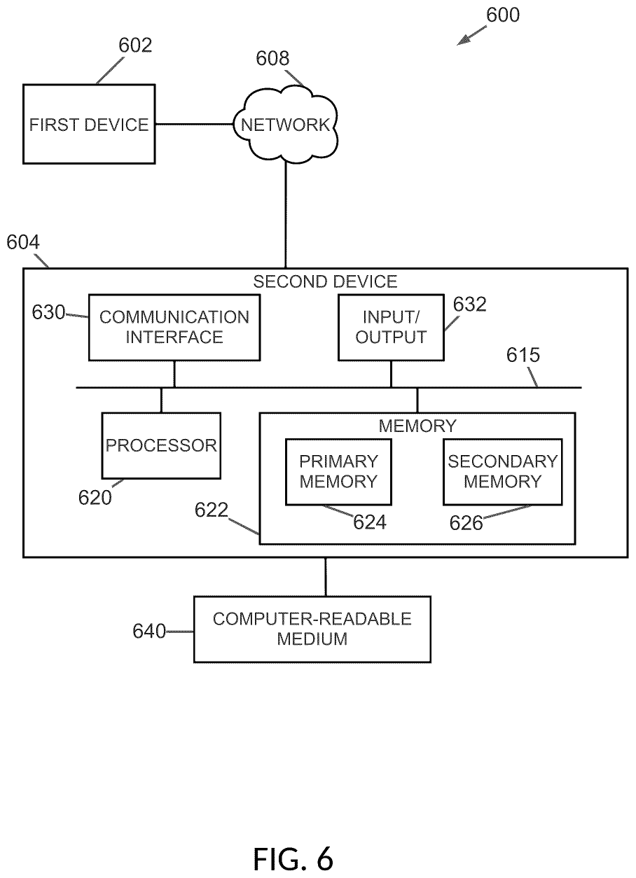

FIG. 1 illustrates an example apparatus 100 including storage circuitry 103 to store an IC cell design 105, first verification operation parameters 111, and second operation parameters 113. The storage circuitry 103 may comprise any type of storage circuitry, such as, for example, a memory device (e.g., random access memory (RAM), persistent memory, processor cache, and/or the like), a storage device (e.g., a hard-disk drive, flash storage, a solid-state drive, and/or other storage component), a networked storage device (e.g. a storage area network (SAN), network-attached storage (NAS), and/or the like), combinations thereof, and/or the like. As an example, apparatus 100 may comprise a workstation, a server, and/or other computer (see, e.g., FIGS. 2, 6).

As illustrated, storage circuitry 103 may store an IC cell design 105. For example, IC cell design 105 may comprise a design including a physical layout for a standard cell. For example, IC cell design 105 may comprise a design for any IC component (the “cell device”), such as, for example, boolean gates (e.g., AND, OR, NAND, XOR, NOT, etc.), sequential logic components (e.g., flip-flops, latches, etc . . . ), as well as more complex circuit elements (e.g., buffers, adders, muxed D-type flip-flops, clock gates, etc . . . ). In some implementations, cell design 105 may comprise a design for an archetype standard cell upon which variant standard cells will be based. In further implementations, cell design 105 may comprise a design for a functional variant of an archetypal cell, such as, for example, a variant having a different threshold voltage, drive strength, beta ratio, and/or the like. In various implementations, cell design 105 may be include one or more files such as Layout Exchange Format (LEF) files and/or the like.

In some implementations, IC cell design 105 may include designs 107 for the physical layout of a plurality of IC layers comprising the cell device. For example, the layers may correspond to various processing steps of an IC fabrication process, such as a lithographic process such as multi-patterning lithography, extreme ultraviolet (EUV) lithography, and/or the like. In various implementations, the particular layers included in designs 107 may vary according to device type, fabrication process, fabrication foundry, and/or other considerations. In some implementations, layer designs 107 may include layers corresponding to active device components, termed “Front End Of The Line” (FEOL) layers, such as, for example, active layers, fin layers, polysilicon (“poly”) layers, cut layers, P-type and N-type doping layers, P-type and N-type well layers, and/or the like. Layer designs 107 may further include layers corresponding to local interconnects within a device, termed “Middle End Of The Line” (MEOL) layers, such as, for example, local interconnect gate (LIG) layers, local interconnect source/drain layers, local interconnect cut layers, and/or the like. Layer designs 107 may further include layers corresponding to interconnects, ports, vias, and other metal structures, termed “Back End Of The Line” (BEOL) layers, such as, for example, one or more metal layers (e.g., Metal 0, Metal 1, Metal 2, etc.), one or more via layers (e.g., Via 0, Via 1, Via 2, etc . . . ), and/or the like. In some implementations, layer designs 107 may include position parameters for various layers. The position parameters may define the position of features of the different layers. For example, the position parameters may comprise location-identifying coordinates and/or other like information elements.

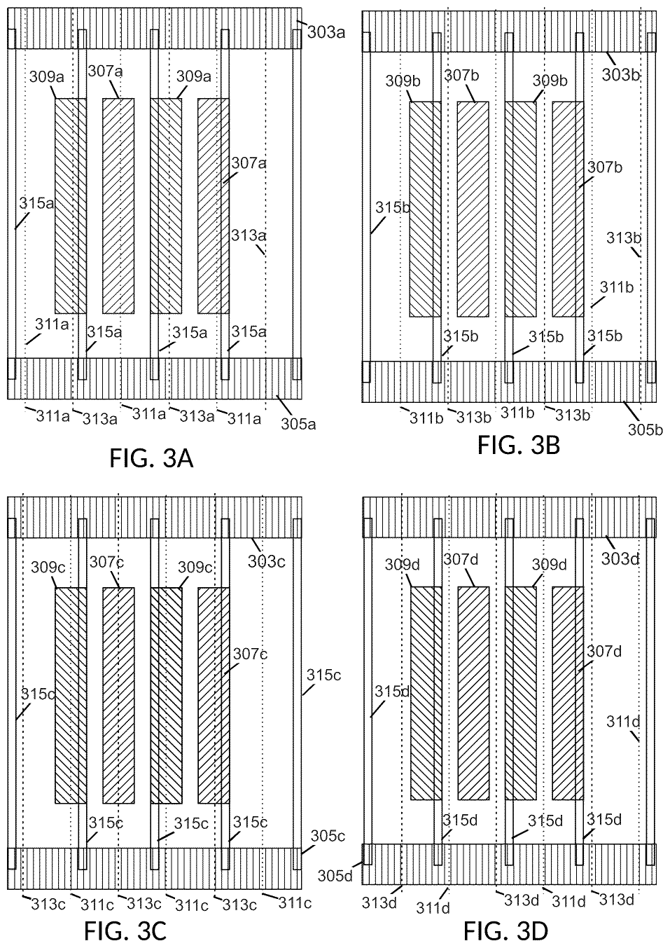

In some implementations, IC cell design 105 may further include alternative position parameters 109 associated with a subset of the respective IC layer layout designs 107. The subset of the layer layout designs 107 may correspond to layers of an electrically equivalent, physical variant that may differ from their archetype cell. For example, a standard cell may have physical variants to accommodate issues with placeability due to misalignment of specified pitches between layer elements. As an example, a metal 1 layer may have a pitch that is smaller than a contacted poly pitch (CPP) of a lower layer (e.g., ⅔ of the CPP), which may limit placeability of an archetypal cell (see, e.g., FIGS. 3A-D) to locations where both pitches align. In this example, layout variant cells may be provided with the metal 1 layer shifted to accommodate different pitch alignments (such as a left shift and a right shift by ⅓ of the CPP). Continuing the example, the subset of the IC layer layout designs 107 may include the metal 1 layer and associated layers that would be modified to accommodate the metal 1 layer (e.g., via layers and higher metal layers). In some cases, the subset of the layer layout designs 107 may comprise the BEOL layers or a subset thereof. In other cases the subset may include MEOL and/or FEOL layers.

Compared to its base cell, features of one or more layers of a layout variant may have different positions. For instance, features may be translated, rotated, reflected, and/or otherwise transformed. In some implementations, alternative position parameters 109 may correspond to a rigid transformation of corresponding respective position parameters of the subset of the respective IC layer layout designs. For example, alternative position parameters 109 may correspond to a translation/shift, rotation, and/or reflection of the features of the subset of the IC layer layout designs. In some implementations, alternative position parameters 109 may correspond to a common transformation of all the layers in the subset. In further implementations, alternative position parameters 109 may correspond to different transformations for different layers in the subset. In some implementations, alternative position parameters 109 may be included in their corresponding IC layer layout designs 107. For instance, alternative position parameters 109 may be included as layer and/or feature metadata. In further implementations, alternative position parameters 109 may be included elsewhere in IC cell design 105. For instance, alternative position parameters 109 may be included in configuration information, such as a configuration file. As an example, IC cell design 105 may include a configuration file providing alternative position parameters 109 identified with their associated layers.

In various implementations, alternative position parameters 109 may correspond to any configuration of one or more transformations. For example, parameters 109 may correspond to a layout variant where all features of a subset of layers are shifted by the same amount (e.g., the BEOL layers being shifted left or right by x nm). As another example, parameters 109 may correspond to a layout variant where the features of different layers are transformed in different ways. For instance, parameters 109 may correspond to a layout variant where features of a first layer are translated by a different distance than features of a second layer (e.g., Metal 1 being shifted by x nm and Metal 2 being shifted by y nm; or the BEOL layers being shifted by x nm and the MEOL layers being shifted by y nm, etc . . . ).

In some implementations, storage circuitry 103 may further store parameters 111, 113 for verification operations. For example, the verification operations may include physical verification operations to verify the manufacturability and/or functionality of IC cell design 105. In some implementations, verification operation parameters 111, 113 may identify verification operations to be performed, inputs to the verification operations, and/or the like. As an example, the verification operations may include design rule checks, such as, for example; boolean checks, which may identify forbidden and/or required regions for layers as per cell architecture; context checks, which involve placing the cell under verification next to other cells and running various design rule checks; pin checks, which may identify pin hit-points and determine pin accessibility; porosity checks, which may evaluate the ability of the cell to connect to power, such as drain/source supply voltages (VDD/VSS); fabric checks, which may involve checking engineering change order (ECO) cells against their corresponding standard cells, for example, to find discrepancies in the FEOL layers between them; custom checks, which may be scripts to verify custom architectural specifications; and/or other like operations. In some implementations, the first and second verification operations may be different design rule checks. For instance, the first verification operation may be a design rule check for a process technology rule provided by a fabrication facility (e.g., foundry) and/or other standardized verification operation, while the second verification operation may be a design rule check for a custom and/or layout variant-specific rule. In further implementations, the first and second verification operations may be design rule checks for a common design rule, which may be executed in a first instance based on position parameters and in a second instance based on a combination of position parameters and alternative position parameters. For instance, a minimum spacing rule check may be performed on the IC cell design 105 and on the IC cell design 105 transformed according to the alternative position parameters.

In some implementations, verification operation parameters 111, 113 may include first verification operation parameters 111 and second verification operation parameters 113. First verification operation parameters 111 may be based at least in part on the position parameters included in IC layer layout designs 107. For example, first verification operation parameters 111 may define a set of verification operations to be performed on the base cell design included in the IC layer layout designs 107. Second verification operation parameters 113 may be based at least in part on alternative position parameters 109 for a subset of the layers and the position parameters for layers in the complement to the subset (e.g., the layers distinct from the subset of the layers). In some cases, second verification operation parameters 113 may be based at least in part on the specific layout variants that will be generated based on cell design 105. For example, second verification operation parameters 113 may identify a subset of layers to be transformed in view of alternate position parameters 109 and/or one or more verification operations to be performed on the transformed IC cell design 105.

In some implementations, verification operation parameters 113 may be based at least in part on corresponding alternative position parameters 109. For example, second verification operation parameters 113 and/or alternate position parameters 109 may correspond to different types of layout variants. As an example, a first set of layout variants may correspond to shifting features of a first subset of layers (e.g., a left/West shift, a right/East shift, an up/North shift, a down/South shift, and/or combinations thereof), while a second set of layout variants may correspond to rotating features of a second subset of layers (e.g., a counterclockwise and/or clockwise rotation of 90°, a rotation of 180°). In this example, second verification operation parameters 113 may comprise instructions to perform one or more design rule checks for the shifted variants in view of translation-based alternative position parameters 109 and one or more design rule checks for the rotated variants in view of rotation-based alternative position parameters 109. In these implementations, the subsets of layers for different layout variants may have some or all layers in common and/or may have different layers.

FIG. 2 illustrates an example apparatus 200 including a processor 201 and storage circuitry 103. For example, apparatus 200 may comprise an implementation of apparatus 100 as described with respect to FIG. 1. As a further example, apparatus 200 may comprise a high-performance computing system, such as a computer cluster and/or grid. In some implementations, apparatus 200 may be implemented as one or more computing devices as discussed with respect to FIG. 6. Apparatus 200 may include one or more processors 201 to execute verification operations on IC cell design 105. For example, processor 201 may include one or more central processing units (CPU), one or more graphics processing units (GPU), combinations thereof, and/or the like.

In some implementations, processor 201 may execute a first verification operation using first verification operation parameters 111 and execute a second verification operation using second verification operation parameters 113, as described with respect to FIG. 1. Processor 201 may provide verification results based on the executed verification operations. For example, the verification results may be provided as a listing of specific design rule violations and/or an indication that IC cell design 105 has passed the verification procedure. In further implementations, the verification results may be displayed on a graphical user interface (GUI), for instance via indicators on a display of the IC cell design 105.

FIGS. 3A-3D provide examples of a baseline IC layout and layout variants to illustrate various aspects of implementations. For ease of explanation, a limited number of layers are illustrated. In particular, the layouts include power structures such as VDD 303a-d, and VSS 305a-d, polysilicon gate structures 315a-d, and metal 1 structures 307a-d, 309a-d. In this example, the metal 1 layer is a dual-patterned layer, with metal structures 307a-d corresponding to a first pattern (a “red pattern”) and metal structures 309a-d corresponding to a second pattern (a “green pattern”). Additionally, lines 311a-d indicate red pattern tracks and lines 313a-d indicate green pattern tracks, which indicate allowable placements of corresponding metal structures 307a-d, 309a-d, respectively. For instance, a design that has a green structure 309a-d overlapping a red track 311a-d may cause a design rule violation (e.g., a “color conflict”).

The baseline cell of FIG. 3A has its green metal structures 309a aligned to green tracks 313a (e.g., the midline of structures 309a coincides with corresponding tracks 313a). Likewise, its red metal structures 307a are aligned to red tracks 311a. In the illustrated example, the distance between neighboring color tracks 311a-d, 313a-d (the “metal 1 pitch”) is ⅔ the distance between neighboring poly structures 315a-d (the “contacted poly pitch” or “CPP”). For instance, if the CPP were 57 nm, the metal 1 pitch would be 38 nm. Since this example is dual-patterned, the distance between neighboring tracks of the same color (e.g., green to green or red to red) is twice the metal1 pitch (e.g., 76 nm). Accordingly, tracks 311a-d, 313a-d repeat their alignment with the poly structures 315a-d every fourth CPP. Since the metal tracks and poly structures repeat across the IC, the baseline cell (FIG. 3A) may only legally be placed every fourth CPP (e.g., at 25% of potential sites).

FIGS. 3B-3D illustrate the other three potential placements and the misalignment that would occur if the cell were placed as illustrated. Every shift of 1 CPP to the right corresponds to an additional 19 nm relative displacement (e.g., ⅓ of 57 nm or 57 nm-38 nm). FIG. 3B illustrates the result of placing the cell one CPP to the right of the placement in FIG. 3A. In this placement, structures 307b, 309b out of alignment with their corresponding tracks 311b, 313b. FIG. 3C illustrates the results of placing the cell two CPP to the right of the FIG. 3A placement. In this placement, the structures 307c, 309c are shifted by 38 nm (2*19 nm), which corresponds to one metal 1 pitch. Accordingly, metal structures 307c, 309c are aligned with their opposite colored tracks 313c, 311c, respectively. FIG. 3D illustrates the results of placing the cell three CPP to the right of FIG. 3A's placement. In this placement the metal structures 307d, 309d are again misaligned to their respective tracks 311d, 313d by 19 nm.

In this example, physical layout variants may be produced to improve the placeability of the cell. In the illustrated example, layout variants may be created to allow placement at additional sites. For instance, layout variants may be created corresponding to what would be misaligned placements of the base cell. For example, a layout variant with the metal 1 layer shifted right by 19 nm may allow placement in the situation illustrated in FIG. 3B while a layout variant with the metal 1 layer shifted left by 19 nm may allow placement in the situation illustrated in FIG. 3D. Accordingly, in the context of FIG. 1, a layout design 105 for the cell illustrated in FIG. 3A may include alternative position parameters 109 and second verification operation parameters 113 for the metal 1 structures 307a, 309a. For example, the alternative position parameters 109 may indicate a right translation of 19 nm and a left translation of 19 nm, while the second verification operation parameters 113 may identify verification operations to be performed on the layout design 105. If the cell design 105 passes the verification, then layout variants created based on the cell design 105 and/or layout variants of functional variants may be more likely to pass verification as well. If the cell design 105 has verification violations based on the alternative position parameters, then the cell may be redesigned based on this information.

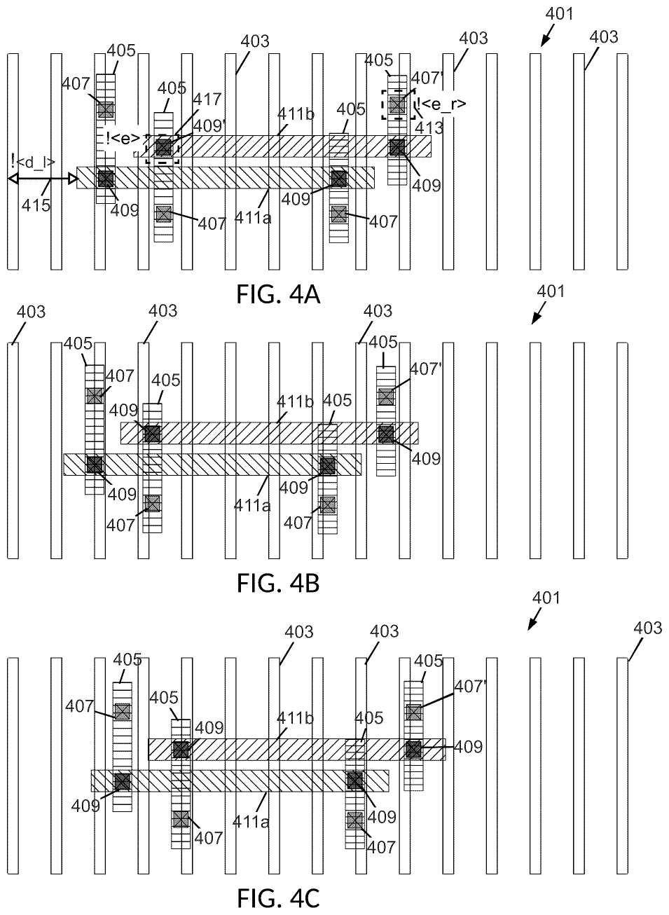

FIGS. 4A-4C illustrate examples of various aspects of an example implementation. FIG. 4A illustrates an example baseline IC cell design laid out according to position parameters associated with the layers of the cell, FIG. 4B illustrates application of alternative position parameters corresponding to a left translation, and FIG. 4C illustrates application of alternative position parameters corresponding to a right translation. For example, FIG. 4A may reflect the output of a verification process, such as performed by apparatus 200 of FIG. 2, while FIGS. 4B and 4C may reflect intermediate states during the verification process. For ease of explanation, IC cell design 401 is illustrated with a poly layer 403, a metal 1 layer 405, a via 0 layer 407, a dual-patterned metal 2 layer 411a, 411b, and a via 1 layer 409. In implementations, IC cell design 401 may include numerous layers below, above, or interspersed with the illustrated layers. For instance, various layers may have corresponding cut layers, a metal 0 layer may be between poly layer 403 and the other layers, the IC cell design 401 may include FEOL layers underneath the poly layer 403, and/or may include further BEOL layers above the illustrated layers.

In the illustrated example, the metal 1 track pitch (not illustrated) is ⅔ the poly 403 pitch. Accordingly, as described with respect to FIGS. 3A-3D, the baseline IC cell design 401 may have a placeability limited to 25% of potential sites. Continuing the example, IC cell design 401 may be used to develop a left translation layout variant and a right translation layout variant, improving placeability to 75% of potential sites. Here, IC cell design 401 may include alternative position parameters associated with metal 1 layer 405 corresponding to a left translation of the metal 1 structures 405. Further, IC cell design 401 may include alternative position parameters associated with metal 1 layer 405 corresponding to a right translation of the metal 1 structures 405. For instance, with pitch dimensions as described with respect to FIGS. 3A-D, the alternative position parameters may indicate a 19 nm left and right translation.

In some implementations, various layers associated with metal 1 layer 405 may have associated alternative position parameters. In the illustrated implementation, via 0 layer 407, metal 2 layer 411a, 411b, and via 1 layer 409 may have associated alternative position parameters corresponding to left and right translations. In this example, layers 407, 411a-411b, 409 may have alternative position parameters indicating the same translation as metal 1 layer 405. As discussed above, in further examples, the left and right translation distances might vary for different layers. FIGS. 4B and 4C illustrate a left and right translation of these layers, respectively.

In some implementations, IC cell design 401 may include first verification operation parameters to be executed based on the position parameters associated with the IC cell design. For example, the first verification operation parameters may specify one or more design rule checks to be performed on the IC design 401 based on the position parameters defining the layout illustrated in FIG. 4A. IC cell design 401 may further include second verification operation parameters to be executed based on the alternative position parameters of layers 405 407, 411a-411b, 409 and the position parameters of the other layers (e.g., poly layer 403 and unillustrated layers). For example, the second verification operation parameters may specify one or more design rule checks to be performed on the configurations illustrated in FIGS. 4B and 4C.

In some implementations, output of the verification operations may be associated with the IC cell design 401. As an example result of a verification operation based on the position parameters, via 409′ has provoked an enclosure violation 417 <e>. As example results based on the alternative position parameters, via 407′ has an enclosure rule violation 413 (<e_r>) corresponding to the right-shifted alternative positions (e.g., FIG. 4C). As another example, metal 2 structure 411a has a distance-to-border violation 415 corresponding to the left-shifted alternative positions (e.g., FIG. 4B). Accordingly, an IC cell designer may redesign the IC cell 401 to avoid these violations and thereby avoid later violations that may be encountered during development of a layout variant cell.

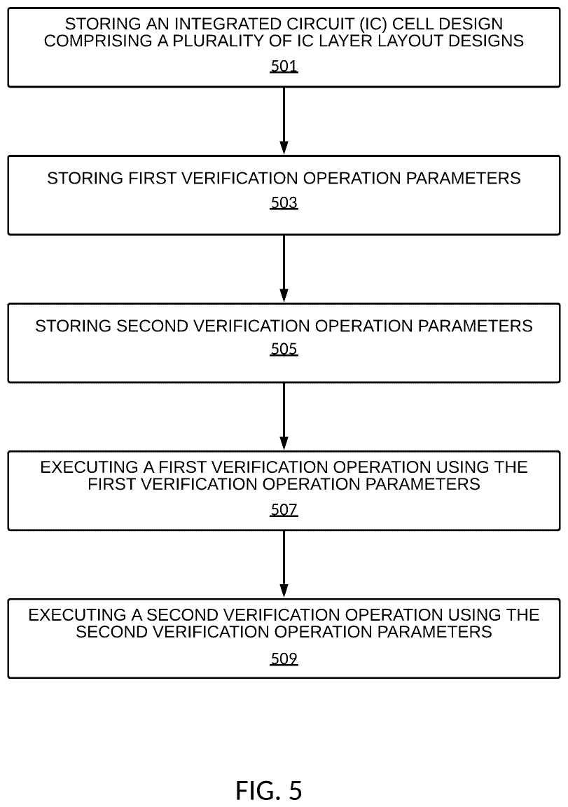

FIG. 5 illustrates an example method of operation in accordance with an implementation. For example, the method may be performed by an apparatus such as apparatus 100 of FIG. 1, apparatus 200 of FIG. 2, and/or one or more devices 602, 604 of FIG. 6. For example, the method may be performed using one or more IC design tools, such as electronic design automation (EDA) tools.

In some implementations, the method may include operation 501, which may include storing an integrated circuit (IC) cell design comprising a plurality of IC layer layout designs. In some cases, respective IC layer layout designs may comprise respective position parameters. As discussed above, the respective position parameters may define features of the IC layers, such as position and shapes of structures and/or cuts. In some implementations, the IC cell design may further include respective alternative position parameters associated with a subset of the respective IC layer layout designs.

In some cases, the alternative position parameters may correspond to a rigid transformation of corresponding respective position parameters of the subset of the respective IC layer layout designs, such as, for example, a translation, rotation, and/or reflection. The rigid translation may correspond to a type of layout variant, such as, for instance, a translation of a subset of the IC layers corresponding to layout variants to compensate for pitch misalignments (e.g., as discussed in FIGS. 3A-D). In further implementations, the respective alternative position parameters may correspond to a plurality of rigid transformations of corresponding respective position parameters. For example, the alternative position parameters may correspond to a translation of a first layer by a first distance, a rotation of a second layer, a translation of a third layer by a second distance, and so-on. In further implementations, the IC cell design may include different sets of alternative position parameters for different subsets of the layers. For instance, this may be implemented when an IC cell design will have multiple different types of layout variants created.

In some implementations, the example method may further include operation 503, which may include storing first verification operation parameters based at least in part on the respective position parameters. For example, as discussed above, the first verification operation parameters may define one or more verification operations, such as design rule checks, that are to be performed on the IC design as reflected by the position parameters. For instance, the first verification operation parameters may indicate verification operation parameters that may be performed without application of the alternative position parameters.

In some implementations, the example method may further include operation 505, which may include storing second verification operation parameters. The second verification operation parameters may be based at least in part on the respective alternative position parameters associated with the subset of the respective IC layer layout designs and the respective position parameters of the respective IC layer layout designs corresponding to a complement of the subset. For example, the second verification operation parameters may identify one or more verification operations to be performed, which alternative position parameters to use during the verification operation(s), and/or which layers should have their alternate positions applied and which should have their baseline positions applied. In further implementations, such as those where multiple layout variant types are planned, operation 505 may include storing corresponding verification operation parameters for each rigid transformation of the plurality of rigid transformations.

In some implementations, the example method may further include operations 507 and 509. Operation 507 may include executing a first verification operation using the first verification operation parameters and operation 509 may include executing a second verification operation using the second verification operation parameters. For example, operations 507 and 509 may be performed via an IC design verification tool, such as, for example, a design rule checking tool. In some implementations, operations 507 and 509 may be performed by a processor such as processor 201 of FIG. 2. For example, operations 507 and 509 may be performed by a workstation, server, computer cluster, and/or other computer system. In further implementations, operations 507 and 509 may include generating and providing verification operation results, such as an identification of one or more design rule violations and/or an indication of the IC design passing the verification operations. In some implementations, the results of operation 509 may be associated with a particular transformation, set of alternative position parameters, subset of layers, and/or the like, for example, as discussed with respect to FIGS. 4A-4C.

FIG. 6 illustrates an example system 600 embodiment of an network-connected device providing aspects of an IC design infrastructure. In one example embodiment, as shown in FIG. 6, a system embodiment may comprise a local network (e.g., a second device 604 and a computer-readable medium 640) and/or another type of network, such as a computing and/or communications network. For purposes of illustration, therefore, FIG. 6 shows an embodiment 600 of a system that may be employed to implement either type or both types of networks. For example, system 600 may implement one or more aspects of the system illustrated with respect to FIGS. 1-5 For instance, first device 602 may represent a computing device to execute an EDA tool, while second device 604 may represent server and/or computer cluster to execute a IC verification tool. Of course, the roles of devices 602, 604 may be interchanged.

Network 608 may comprise one or more network connections, links, processes, services, applications, and/or resources to facilitate and/or support communications, such as an exchange of communication signals, for example, between a computing device, such as 602, and another computing device, such as 604. For example, network 608 may comprise wireless and/or wired communication links, the Internet, a local area network (LAN), a wide area network (WAN), or any combination thereof.

Example devices in FIG. 6 may comprise features, for example, of a client computing device and/or a server computing device, in an implementation. It is further noted that the term computing device, in general, whether employed as a client and/or as a server, or otherwise, refers at least to a processor and a memory connected by a communication bus. Likewise, in the context of the present disclosure at least, this is understood to refer to sufficient structure within the meaning of 35 § USC 15 (f) so that it is specifically intended that 35 § USC 15 (f) not be implicated by use of the term “computing device” and/or similar terms; however, if it is determined, for some reason not immediately apparent, that the foregoing understanding cannot stand and that 35 § USC 15 (f) therefore, necessarily is implicated by the use of the term “computing device” and/or similar terms, then, it is intended, pursuant to that statutory section, that corresponding structure, material and/or acts for performing one or more functions be understood and be interpreted to be described at least in FIGS. 1-6 of the present disclosure.

In some implementations, first and/or second devices 602, 604 may be capable of rendering a graphical user interface (GUI), for example, so that a user-operator may engage in system use. For instance, first and/or second devices 602, 604 may be capable of interacting with a user via one or more EDA tool interfaces of an EDA suite. In other embodiments, first and/or second devices 602, 604 may operate in a “headless” manner without a GUI.

In some implementations, computing device 602 may interface with computing device 604, which may, for example, also comprise features of a client computing device and/or a server computing device, in an embodiment. Processor (e.g., processing device) 620 and memory 622, which may comprise primary memory 624 and secondary memory 626, may communicate by way of a communication bus 615, for example. The term “computing device,” in the context of the present disclosure, refers to a system and/or a device, such as a computing apparatus, that includes a capability to process (e.g., perform computations) and/or store digital content, such as electronic files, electronic documents, measurements, text, images, video, audio, etc. in the form of signals and/or states. Thus, a computing device, in the context of the present disclosure, may comprise hardware, software, firmware, or any combination thereof (other than software per se). Computing device 604, as depicted in FIG. 6, is merely one example, and claimed subject matter is not limited in scope to this particular example.

In FIG. 6, computing device 604 may provide one or more sources of executable computer instructions in the form physical states and/or signals (e.g., stored in memory states), for example. For example, computing device 604 may perform the processes described with respect to FIGS. 5 and/or implement the components described with respect to FIGS. 1 and/or 2. For instance, computing device 604 may perform one or more verification operations 507, 509. Computing device 604 may communicate with computing device 602 by way of a network connection, such as via network 608, for example. As previously mentioned, a connection, while physical, may not necessarily be tangible. Although computing device 604 of FIG. 6 shows various tangible, physical components, claimed subject matter is not limited to computing devices having only these tangible components as other implementations and/or embodiments may include alternative arrangements that may comprise additional tangible components or fewer tangible components, for example, that function differently while achieving similar results. Rather, examples are provided merely as illustrations. It is not intended that claimed subject matter be limited in scope to illustrative examples.

Memory 622 may comprise any non-transitory storage circuitry. For example, memory 622 may comprise an implementation of storage circuitry 103 of FIGS. 1, 2. Memory 622 may comprise, for example, primary memory 624 and secondary memory 626, additional memory circuits, mechanisms, or any combination thereof may be used. Memory 622 may comprise, for example, random access memory, read only memory, etc., such as in the form of one or more storage devices and/or systems, such as, for example, a disk drive, a solid-state memory drive, etc.

Memory 622 may be utilized to store a program of executable computer instructions. For example, processor 620 may fetch executable instructions from memory and proceed to execute the fetched instructions. Memory 622 may also comprise a memory controller for accessing device readable-medium 640 that may carry and/or make accessible digital content, which may include code, and/or instructions, for example, executable by processor 620 and/or some other device, such as a controller, as one example, capable of executing computer instructions, for example. Under direction of processor 620, a non-transitory memory, such as memory cells storing physical states (e.g., memory states), comprising, for example, a program of executable computer instructions, may be executed by processor 620 and able to generate signals to be communicated via a network, for example, as previously described. Generated signals may also be stored in memory. As an example, computer-readable medium 640 may store instructions that, responsive to execution by processor 620, cause the processor to perform or control performance of operations described above.

Memory 622 may store electronic files and/or electronic documents, such as relating to one or more IC cell designs, and may also comprise a device-readable medium that may carry and/or make accessible content, including code and/or instructions, for example, executable by processor 620 and/or some other device, such as a controller, as one example, capable of executing computer instructions, for example.

It has proven convenient at times, principally for reasons of common usage, to refer to such physical signals and/or physical states as bits, values, elements, parameters, symbols, characters, terms, numbers, numerals, measurements, content and/or the like. It should be understood, however, that all of these and/or similar terms are to be associated with appropriate physical quantities and are merely convenient labels. Unless specifically stated otherwise, as apparent from the preceding discussion, it is appreciated that throughout this specification discussions utilizing terms such as “processing,” “computing,” “calculating,” “determining”, “establishing”, “obtaining”, “identifying”, “selecting”, “generating”, and/or the like may refer to actions and/or processes of a specific apparatus, such as a special purpose computer and/or a similar special purpose computing and/or network device. In the context of this specification, therefore, a special purpose computer and/or a similar special purpose computing and/or network device is capable of processing, manipulating and/or transforming signals and/or states, typically in the form of physical electronic and/or magnetic quantities, within memories, registers, and/or other storage devices, processing devices, and/or display devices of the special purpose computer and/or similar special purpose computing and/or network device. In the context of this particular disclosure, as mentioned, the term “specific apparatus” therefore includes a general purpose computing device and/or system of computing devices, such as a general purpose computer, once it is programmed to perform particular functions, such as pursuant to program software instructions.

Processor 620 may comprise one or more circuits, such as digital circuits, to perform at least a portion of a computing procedure and/or process. Byway of example, but not limitation, processor 620 may comprise one or more processors, such as controllers, microprocessors, microcontrollers, application specific integrated circuits, digital signal processors, programmable logic devices, field programmable gate arrays, graphics processing units, hardware accelerators, the like, or any combination thereof. In various implementations and/or embodiments, processor 620 may perform signal processing, typically substantially in accordance with fetched executable computer instructions, such as to manipulate signals and/or states, to construct signals and/or states, etc., with signals and/or states generated in such a manner to be communicated and/or stored in memory, for example.

FIG. 6 also illustrates device 604 as including a component 632 operable with input/output devices, for example, so that signals and/or states may be appropriately communicated between devices, such as device 604 and an input device and/or device 604 and an output device. A user may make use of an input device, such as a microphone, computer mouse, stylus, track ball, keyboard, and/or any other similar device capable of receiving user actions and/or movements as input signals. Likewise, a user may make use of an output device, such as a speaker, indicator light, display, printer, etc., and/or any other device capable of providing signals and/or generating stimuli for a user, such as visual stimuli, audio stimuli and/or other similar stimuli. For instance, a user may make use, in whole or in part, of input/output devices to display and interact with a user during various stages of IC cell design operations, such as described with respect to FIGS. 4A-C.

Unless otherwise indicated, in the context of the present disclosure, the term “or” if used to associate a list, such as A, B, or C, is intended to mean A, B, and C, here used in the inclusive sense, as well as A, B, or C, here used in the exclusive sense. With this understanding, “and” is used in the inclusive sense and intended to mean A, B, and C; whereas “and/or” can be used in an abundance of caution to make clear that all of the foregoing meanings are intended, although such usage is not required. In addition, the term “one or more” and/or similar terms is used to describe any feature, structure, characteristic, and/or the like in the singular, “and/or” is also used to describe a plurality and/or some other combination of features, structures, characteristics, and/or the like. Furthermore, the terms “first,” “second” “third,” and the like are used to distinguish different aspects, such as different components, as one example, rather than supplying a numerical limit or suggesting a particular order, unless expressly indicated otherwise. Likewise, the term “based on” and/or similar terms are understood as not necessarily intending to convey an exhaustive list of factors, but to allow for existence of additional factors not necessarily expressly described.

Furthermore, it is intended, for a situation that relates to implementation of claimed subject matter and is subject to testing, measurement, and/or specification regarding degree, to be understood in the following manner. As an example, in a given situation, assume a value of a physical property is to be measured. If alternatively reasonable approaches to testing, measurement, and/or specification regarding degree, at least with respect to the property, continuing with the example, is reasonably likely to occur to one of ordinary skill, at least for implementation purposes, claimed subject matter is intended to cover those alternatively reasonable approaches unless otherwise expressly indicated.

In the preceding description, various aspects of claimed subject matter have been described. For purposes of explanation, specifics, such as amounts, systems and/or configurations, as examples, were set forth. In other instances, well-known features were omitted and/or simplified so as not to obscure claimed subject matter. While certain features have been illustrated and/or described herein, many modifications, substitutions, changes and/or equivalents will now occur to those skilled in the art. It is, therefore, to be understood that the appended claims are intended to cover all modifications and/or changes as fall within claimed subject matter.

Some configurations of the present techniques are described by the following numbered clauses:

Clause 1. An apparatus, comprising:
storage circuitry to store an integrated circuit (IC) cell design comprising a plurality of IC layer layout designs, wherein respective IC layer layout designs comprise respective position parameters, and the IC cell design further comprises respective alternative position parameters associated with a subset of the respective IC layer layout designs; and wherein
the storage circuitry is to further store first verification operation parameters and second verification operation parameters, wherein
the first verification operation parameters are based at least in part on the respective position parameters, and
the second verification operation parameters are based at least in part on the respective alternative position parameters associated with the subset of the respective IC layer layout designs and the respective position parameters of the respective IC layer layout designs corresponding to a complement of the subset.

Clause 2. The apparatus of clause 1, wherein the subset of the respective IC layer layout designs comprise back-end-of-line (BEOL) layer layout designs.

Clause 3. The apparatus of any preceding clause, wherein the respective alternative position parameters correspond to a rigid transformation of corresponding respective position parameters of the subset of the respective IC layer layout designs.

Clause 4. The apparatus of any preceding clause, wherein the respective alternative position parameters correspond to a plurality of rigid transformations of corresponding respective position parameters of the subset of the respective IC layer layout designs.

Clause 5. The apparatus of any preceding clause, wherein the storage circuitry is to store corresponding second verification operation parameters for each rigid transformation of the plurality of rigid transformations, wherein the corresponding verification operation parameters are based at least in part on the respective alternative position parameters.

Clause 6. The apparatus of any preceding clause, wherein a first rigid translation of the plurality of rigid translations comprises a first translation by a first distance and a second translation by a second distance.

Clause 7. The apparatus of any preceding clause, further comprising:
a processor to execute a first verification operation using the first verification operation parameters and to execute a second verification operation using the second verification operation parameters.

Clause 8. The apparatus of any preceding clause, where the first verification operation comprises a first design rule check and the second verification operation comprises a second design rule check.

Clause 9. The apparatus of any preceding clause, wherein the first design rule check and the second design rule check correspond to a common design rule.

Clause 10. A method, comprising:
storing an integrated circuit (IC) cell design comprising a plurality of IC layer layout designs, wherein respective IC layer layout designs comprise respective position parameters, and the IC cell design further comprises respective alternative position parameters associated with a subset of the respective IC layer layout designs;
storing first verification operation parameters based at least in part on the respective position parameters; and
storing second verification operation parameters, the second verification operation parameters are based at least in part on the respective alternative position parameters associated with the subset of the respective IC layer layout designs and the respective position parameters of the respective IC layer layout designs corresponding to a complement of the subset.

Clause 11. The method of clause 10, wherein the subset of the respective IC layer layout designs comprise back-end-of-line (BEOL) layer layout designs.

Clause 12. The method of clauses 10 or 11, wherein the respective alternative position parameters correspond to a rigid transformation of corresponding respective position parameters of the subset of the respective IC layer layout designs.

Clause 13. The method of any of clauses 10-12, wherein the respective alternative position parameters correspond to a plurality of rigid transformations of corresponding respective position parameters of the subset of the respective IC layer layout designs.

Clause 14. The method of any of clauses 10-13, further comprising: storing corresponding verification operation parameters for each rigid transformation of the plurality of rigid transformations, wherein the corresponding verification operation parameters are based at least in part on the respective alternative position parameters.

Clause 15. The method of any of clauses 10-14, further comprising:
executing a first verification operation using the first verification operation parameters; and
executing a second verification operation using the second verification operation parameters.

Clause 16. The method of any of clauses 10-15, wherein the first verification operation comprises a first design rule check and the second verification operation comprises a second design rule check.

Clause 17. The method of any of clauses 10-16, wherein the first design rule check and the second design rule check correspond to a common design rule.

Clause 18. A non-transitory computer-readable medium to store computer-readable code comprising:
code to store an integrated circuit (IC) cell design comprising a plurality of IC layer layout designs, wherein respective IC layer layout designs comprise respective position parameters, and the IC cell design further comprises respective alternative position parameters associated with a subset of the respective IC layer layout designs;
code to store first verification operation parameters based at least in part on the respective position parameters; and
code to store second verification operation parameters, wherein the second verification operation parameters are based at least in part on the respective alternative position parameters associated with the subset of the respective IC layer layout designs and the respective position parameters of the respective IC layer layout designs corresponding to a complement of the subset.

Clause 19. The non-transitory computer-readable medium of clause 18, wherein the respective alternative position parameters correspond to a rigid transformation of corresponding respective position parameters of the subset of the respective IC layer layout designs.

Clause 20. The non-transitory computer-readable medium of clause 18 or 19, further comprising:
code to execute a first verification operation using the first verification operation parameters; and
code to execute a second verification operation using the second verification operation parameters.

Clause 21. A non-transitory computer-readable medium to store computer-readable code comprising code to perform the method of any of clauses 11-17.

1. An apparatus, comprising:
storage circuitry to store an integrated circuit (IC) cell design comprising a plurality of IC layer layout designs, wherein respective IC layer layout designs comprise respective position parameters, and the IC cell design further comprises respective alternative position parameters associated with a subset of the respective IC layer layout designs; and wherein
the storage circuitry is to further store first verification operation parameters and second verification operation parameters, wherein
the first verification operation parameters are based at least in part on the respective position parameters, and
the second verification operation parameters are based at least in part on the respective alternative position parameters associated with the subset of the respective IC layer layout designs and the respective position parameters of the respective IC layer layout designs corresponding to a complement of the subset.

2. The apparatus of claim 1, wherein the subset of the respective IC layer layout designs comprise back-end-of-line (BEOL) layer layout designs.

3. The apparatus of claim 1, wherein the respective alternative position parameters correspond to a rigid transformation of corresponding respective position parameters of the subset of the respective IC layer layout designs.

4. The apparatus of claim 3, wherein the respective alternative position parameters correspond to a plurality of rigid transformations of corresponding respective position parameters of the subset of the respective IC layer layout designs.

5. The apparatus of claim 4, wherein the storage circuitry is to store corresponding second verification operation parameters for each rigid transformation of the plurality of rigid transformations, wherein the corresponding verification operation parameters are based at least in part on the respective alternative position parameters.

6. The apparatus of claim 4, wherein a first rigid translation of the plurality of rigid translations comprises a first translation by a first distance and a second translation by a second distance.

7. The apparatus of claim 1, further comprising:
a processor to execute a first verification operation using the first verification operation parameters and to execute a second verification operation using the second verification operation parameters.

8. The apparatus of claim 7, where the first verification operation comprises a first design rule check and the second verification operation comprises a second design rule check.

9. The apparatus of claim 8, wherein the first design rule check and the second design rule check correspond to a common design rule.

10. A method, comprising:
storing an integrated circuit (IC) cell design comprising a plurality of IC layer layout designs, wherein respective IC layer layout designs comprise respective position parameters, and the IC cell design further comprises respective alternative position parameters associated with a subset of the respective IC layer layout designs;
storing first verification operation parameters based at least in part on the respective position parameters; and
storing second verification operation parameters, the second verification operation parameters are based at least in part on the respective alternative position parameters associated with the subset of the respective IC layer layout designs and the respective position parameters of the respective IC layer layout designs corresponding to a complement of the subset.

11. The method of claim 10, wherein the subset of the respective IC layer layout designs comprise back-end-of-line (BEOL) layer layout designs.

12. The method of claim 10, wherein the respective alternative position parameters correspond to a rigid transformation of corresponding respective position parameters of the subset of the respective IC layer layout designs.

13. The method of claim 10, wherein the respective alternative position parameters correspond to a plurality of rigid transformations of corresponding respective position parameters of the subset of the respective IC layer layout designs.

14. The method of claim 13, further comprising:
storing corresponding verification operation parameters for each rigid transformation of the plurality of rigid transformations, wherein the corresponding verification operation parameters are based at least in part on the respective alternative position parameters.

15. The method of claim 10, further comprising:
executing a first verification operation using the first verification operation parameters; and
executing a second verification operation using the second verification operation parameters.

16. The method of claim 15, wherein the first verification operation comprises a first design rule check and the second verification operation comprises a second design rule check.

17. The method of claim 16, wherein the first design rule check and the second design rule check correspond to a common design rule.

18. A non-transitory computer-readable medium to store computer-readable code comprising:
code to store an integrated circuit (IC) cell design comprising a plurality of IC layer layout designs, wherein respective IC layer layout designs comprise respective position parameters, and the IC cell design further comprises respective alternative position parameters associated with a subset of the respective IC layer layout designs;
code to store first verification operation parameters based at least in part on the respective position parameters; and
code to store second verification operation parameters, wherein the second verification operation parameters are based at least in part on the respective alternative position parameters associated with the subset of the respective IC layer layout designs and the respective position parameters of the respective IC layer layout designs corresponding to a complement of the subset.

19. The non-transitory computer-readable medium of claim 18, wherein the respective alternative position parameters correspond to a rigid transformation of corresponding respective position parameters of the subset of the respective IC layer layout designs.

20. The non-transitory computer-readable medium of claim 18, further comprising:
code to execute a first verification operation using the first verification operation parameters; and
code to execute a second verification operation using the second verification operation parameters.
